(19) United States
(12) Patent Application Publication
(10) Pub. No.: US 2024/0153829 A1
(43) Pub. Date: May 9, 2024

(54) METHOD FOR MANUFACTURING SEMICONDUCTOR DEVICE

(71) Applicant: FUJI ELECTRIC CO., LTD., Kanagawa (JP)

(72) Inventors: Yuusuke OOSHIMA, Matsumoto-city (JP); Takashi YOSHIMURA, Matsumoto-city (JP); Hiroshi TAKISHITA, Matsumoto-city (JP); Shuntaro YAGUCHI, Matsumoto-city (JP)

(21) Appl. No.: 18/492,802

(22) Filed: Oct. 24, 2023

(30) Foreign Application Priority Data
Nov. 8, 2022 (JP) 2022-179140

(51) Int. Cl. H01L 21/66

(52) U.S. Cl. CPC H01L 22/20; H01L 22/12

(57) ABSTRACT

Provided is a method for manufacturing a semiconductor device, wherein the method: obtains correlated information indicating relationship between a process condition under which a doping region is formed and a defect evaluation value of the doping region; forms the doping region in a substrate for evaluation under a set first process condition; obtains a measurement value of the defect evaluation value of the substrate for evaluation in which the doping region has been formed; obtains, in the correlated information, the defect evaluation value corresponding to the first process condition as a reference value, and compares the measurement value of the defect evaluation value with the reference value; and adjusts the process condition in a process of manufacturing the semiconductor device by using the substrate for manufacture.

### BACKGROUND

### 1. Technical Field

The present invention relates to a method for manufacturing a semiconductor device.

### 2. Related Art

A technique of implanting an ion such as a proton into a semiconductor substrate is known (see, for example, Patent Document 1). In addition, a technique of detecting a defect in a semiconductor substrate is known (see, for example, Patent Document 2).
Patent Document 1: U52016/0141399
Patent Document 2: Japanese Patent Application Publication No. H5-074730

### BRIEF DESCRIPTION OF THE DRAWINGS

FIG. 1 is a flowchart showing an example of a method for manufacturing a semiconductor device according to one embodiment of the present invention.

FIG. 2 describes an example of a correlated information obtainment step S102.

FIG. 3 describes an example of an implantation step S104.

FIG. 4 is a cross-sectional view schematically showing a state in a substrate for evaluation 130 into which a dopant ion has been implanted.

FIG. 5 illustrates an example of distribution of a carrier concentration in a depth direction of the substrate for evaluation 130 shown in FIG. 4.

FIG. 6 describes a continuation of the implantation step S104.

FIG. 7 is a cross-sectional view schematically showing a state in the substrate for evaluation 130 which has been annealed.

FIG. 8 illustrates an example of distribution of a carrier concentration in a depth direction of the substrate for evaluation 130 shown in FIG. 7.

FIG. 9 describes an example of a measurement value obtainment step S106.

FIG. 10 illustrates an example of a comparison step S108 and an adjustment step S110.

FIG. 11 illustrates an example of first information 161 used to generate correlated information (or approximate line 120).

FIG. 12 illustrates an example of second information 162 used to generate correlated information (or approximate line 120).

FIG. 13 illustrates an example of third information used to generate the second information 162.

FIG. 14 illustrates an example of third information used to generate the second information 162.

FIG. 15 illustrates another example of a doping region 132.

FIG. 16 illustrates an example of a semiconductor ingot 160.

FIG. 17 is a cross-sectional view showing an example of a semiconductor device 100 manufactured in a manufacture step S112.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

In the present specification, one side in a direction parallel to a depth direction of a semiconductor substrate is referred to as “upper” and the other side is referred to as “lower”. One surface of two principal surfaces of a substrate, a layer or some other member is referred to as an upper surface, and the other surface is referred to as a lower surface. “Upper” and “lower” directions are not limited to a direction of gravity, or a direction in which a semiconductor device is mounted.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to variability in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding a donor concentration set as a positive ion concentration to an acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies electrons. A hydrogen donor may be a donor in which at least a vacancy (V) and hydrogen (H) are attached together. Alternatively, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate in the present specification, bulk donors of the N type are distributed throughout. A bulk donor is a dopant donor substantially uniformly contained in an ingot during manufacture of the ingot from which the semiconductor substrate is made. The bulk donor in the present example is an element other than hydrogen. A bulk donor dopant is, for example, phosphorous, antimony, arsenic, selenium, or sulfur, but the invention is not limited thereto. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by one of a Czochralski method (CZ method), a magnetic-field applied Czochralski method (MCZ method), or a float zone method (FZ method). The ingot in the present example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. Higher oxygen concentration tends to generate a hydrogen donor more easily. A chemical concentration of a bulk donor distributed throughout the semiconductor substrate may be used as a bulk donor concentration, which may be a value from 90% to 100% of the chemical concentration. In addition, a non-doped substrate not containing a dopant such as phosphorous may be used as the semiconductor substrate. In that case, the bulk donor concentration (DO) of the non-doped substrate is, for example, 1×10¹⁰/cm³ or more and 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As an example, a value at 300 K (Kelvin) (about 26.9 degrees Celsius) may be used as the value at room temperature.

In the present specification, a description of a P+ type or an N+ type means a higher doping concentration than that of the P type or the N type, and a description of a P− type or an N-type means a lower doping concentration than that of the P type or the N type. Further, in the specification, a description of a P++ type or an N++ type means a higher doping concentration than that of the P+ type or the N+ type. In the present specification, a unit system is an SI unit system unit system unless otherwise stated in particular. Although a unit of a length may be expressed using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and therefore the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for the donor or acceptor concentration, or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

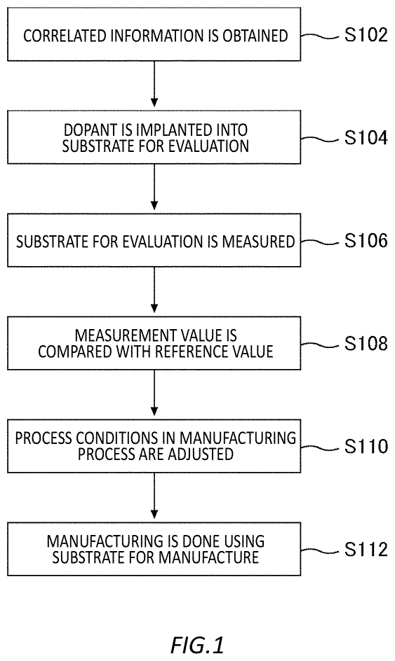

FIG. 1 is a flowchart showing an example of a method for manufacturing a semiconductor device according to one embodiment of the present invention. The semiconductor device may have a power semiconductor element such as an Insulated Gate Bipolar Transistor (IGBT). The semiconductor device in the present example is a vertical device in which principal current flows between an upper surface and a lower surface of the semiconductor substrate, but the semiconductor device may be a horizontal device in which the principal current flows along the upper surface of the semiconductor substrate. The semiconductor substrate in the present example is a disk-shaped wafer cut out from a semiconductor ingot, but the semiconductor substrate may not be a wafer. The semiconductor substrate may be a chip-shaped substrate cut out from the wafer.

In manufacturing the semiconductor device, an initial characteristic of the semiconductor substrate may affect a characteristic of the semiconductor substrate which has undergone a manufacture process. The initial characteristic of the semiconductor substrate refers to the characteristic of the semiconductor substrate before it is put into the process of manufacturing the semiconductor device. The initial characteristic of the semiconductor substrate is, for example, a concentration of an impurity contained in the semiconductor substrate. The initial characteristic of the semiconductor substrate may be the concentration of the impurity contained in the entire semiconductor substrate.

The characteristic of the semiconductor substrate which has undergone the manufacture process may be a structural characteristic or an electrical characteristic of the semiconductor element which has been finished. The structural characteristic is, for example, density of a lattice defect present in a predetermined region. The electrical characteristic is, for example, forward voltage Vf of a diode element, saturation voltage Vce (sat) of the IGBT, leakage current of these elements, a maximum applied voltage value or a maximum applied current value obtained without destruction, or the like. Note that the structural characteristic and the electrical characteristic are not limited to the examples described above. The electrical characteristic of the semiconductor element which has been finished may be an electrical characteristic in a state where a plurality of semiconductor chips are formed on a wafer of the semiconductor substrate and are not divided, or may be an electrical characteristic of each semiconductor chip after the wafer of the semiconductor substrate is divided into individual semiconductor chips through dicing or the like.

In the present specification, impurities contained in the entire semiconductor substrate may be referred to as bulk dopants, bulk donors, or bulk acceptors. As an example, the semiconductor substrate is a silicon substrate, and a bulk dopant may be one of the following elements: phosphorous (P), boron (B), antimony (Sb), or arsenic (As). It may have two types of bulk dopants with different polarities (conductivity types). For example, with a primary bulk dopant as phosphorous, it may have boron, as a secondary bulk dopant, having a concentration lower than a concentration of phosphorous to the extent that the polarity is not reversed.

As an example in which the initial characteristic of the semiconductor substrate affects a characteristic of the semiconductor element, a case will be described in which a hydrogen ion such as a proton is implanted into a partial region of the semiconductor substrate to form a local doping region. When the semiconductor substrate into which the hydrogen ion has been implanted is annealed, a hydrogen donor of a VOH defect, interstitial Si—H, or CiOi-H is formed. A dose amount (/cm²) of the hydrogen ion is set according to a target value of a concentration (/cm³) of the hydrogen donor to be formed in the doping region. However, the concentration of the hydrogen donor to be formed varies depending on a concentration of carbon or oxygen of the semiconductor substrate. Therefore, a carrier concentration in the doping region deviates from the target value, which affects the characteristic of the semiconductor element. Examples of the initial characteristic of the semiconductor substrate can include whether a backside polysilicon coat method is adopted, whether a backside damage method is adopted, or the like. The backside polysilicon coat method deposits polysilicon on one of principal surfaces of the semiconductor substrate (wafer). Forming a polysilicon layer can maintain a gettering effect of capturing an impurity such as a heavy metal in the semiconductor substrate, for a relatively long period of time. The backside damage method produces the gettering effect described above by forming uniformly distributed strains by a sand blasting method or the like on one of the principal surfaces of the semiconductor substrate. Breakdown voltage of the semiconductor substrate varies depending on whether these methods are adopted. Information on whether these methods are adopted may be obtained from a manufacturer of the semiconductor substrate.

A manufacturing method in the present example uses a substrate for evaluation which is a semiconductor substrate for evaluation. The substrate for evaluation is a semiconductor substrate having the initial characteristic equal to that of a substrate for manufacture which is a semiconductor substrate forming the semiconductor device. As an example, two semiconductor substrates cut out from the same semiconductor ingot may be considered to have equal initial characteristics. In addition, if a difference between measurement values of the initial characteristics is within a predetermined range, the initial characteristics of the two semiconductor substrates may be treated as an equal. In addition, if a difference between specification values of initial characteristics of semiconductor substrates provided by the manufacturer of the semiconductor substrate is within a predetermined range, the initial characteristics of the two semiconductor substrates may be treated as an equal. These differences may be, for example, 20% or less, or may be 10% or less.

The manufacturing method in the present example includes a correlated information obtainment step S102, an implantation step S104, a measurement value obtainment step S106, a comparison step S108, an adjustment step S110, and a manufacture step S112. Part or all of processing in the correlated information obtainment step S102, the comparison step S108, and the adjustment step S110 may be performed by an arithmetic processing device such as a computer. Part or all of processing in the implantation step S104, the measurement value obtainment step S106, and the manufacture step S112 may be performed by a semiconductor manufacture device or a measurement device.

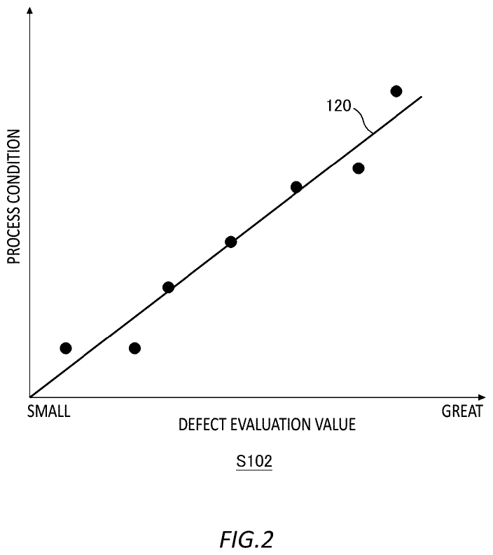

FIG. 2 describes an example of a correlated information obtainment step S102. The correlated information obtainment step S102 obtains correlated information. The correlated information indicates relationship between a process condition for the time when a dopant is implanted into a semiconductor substrate to form a doping region and a defect evaluation value obtained by evaluating density of a defect formed in the doping region. The defect evaluation value in the present example shows a higher value as the defect density is higher.

The process condition includes at least one of a type of a dopant ion to be implanted, a dose amount of the dopant ion, acceleration energy of the dopant ion, and a type of a device for implanting the dopant ion. The type of the implantation device may be classified by a manner in which the dopant ion is generated, may be classified by a manner in which the dopant ion is accelerated, may be classified in terms of a manufacturer of the implantation device, or may be classified in terms of a performance value of the implantation device, for example. The performance value of the implantation device indicates performance of the implantation device, such as an upper limit value or a lower limit value of the acceleration energy, for example.

The defect evaluation value may be a value of the defect density per unit volume (/cm³) of the semiconductor substrate, or may be an indirect value which varies depending on the value of the defect density. As an example, the defect evaluation value is obtained by evaluating, by a Therma Wave method, the defect density in the doping region formed in the upper surface of the semiconductor substrate. The Therma Wave method irradiates a measurement target position of the semiconductor substrate with measurement laser light while irradiating the measurement target position with excitation laser light, and detects reflected light of the measurement laser light. Irradiation with the excitation laser light excites an electron at the measurement target position. As a result of the excited electron being re-attached to a lattice defect at the measurement target position, Thermal vibration is generated. The thermal vibration changes reflectance on a surface of the measurement target position. Since magnitude of the thermal vibration varies depending on the defect density at the measurement target position, intensity of the reflected light of the measurement laser light changes depending on the defect density at the measurement target position. Therefore, the defect density at the measurement target position can be estimated from the intensity of the reflected light. The defect evaluation value may be the intensity of the reflected light detected by the Therma Wave method, or may be a value obtained by performing a predetermined arithmetic operation on the intensity of the reflected light.

The correlated information may be set for each type of an initial characteristic of the semiconductor substrate, or may be set for each range of the initial characteristic. For example, the correlated information may be set for each type of an impurity contained in the semiconductor substrate and for each range of a concentration of each impurity. The correlated information obtainment step S102 obtains the correlated information corresponding to initial characteristics of a substrate for manufacture and a substrate for evaluation.

Each piece of correlated information may be generated from an actual measurement value. In the example of FIG. 2, plotted black circles indicate actual measurement values. The correlated information may be a formula of an approximate line 120 obtained by approximating the plotted actual measurement values with a straight line or a curved line. Note that the correlated information may not be a mathematical formula. The correlated information may be a table indicating correspondence relationship between a plurality of defect evaluation values and a plurality of process conditions, or may indicate relationship between the defect evaluation values and the process conditions in another format.

The example of FIG. 2 shows the correlated information for a case where the process condition includes one parameter. In this case, the correlated information can be defined by one line. In another example, the process condition may include a plurality of parameters. In this case, the correlated information may be information in which one defect evaluation value is associated with each combination of values of the plurality of parameters.

For example, the initial characteristic of the semiconductor substrate includes a type Xi of the impurity (where i is an integer from 1 to j, and j corresponds to the number of types of the impurity) contained in the semiconductor substrate, and a chemical concentration Ci (where i is an integer from 1 to k) of the impurity. In addition, the process condition includes a type Yi of the dopant ion (where i is an integer from 1 to l, and l corresponds to the number of types of the dopant ion) to be implanted, a dose amount Di (where i is an integer from 1 to n) of the dopant ion, acceleration energy Ei (where i is an integer from 1 to o) of the dopant ion, an annealing condition Ai (where i is an integer from 1 to p) of the semiconductor substrate into which the dopant ion has been implanted, and a type Mi of the device for implanting the dopant ion (where i is an integer from 1 to q, and q corresponds to the number of types of the implantation device).

The type Xi of the impurity contained the semiconductor substrate may include at least one of carbon, oxygen, or a bulk dopant. The bulk dopant may include at least one of P, B, Sb, or As. The chemical concentration Ci of the impurity may include a chemical concentration of at least one of carbon, oxygen, or the bulk dopant. The type Yi of the dopant ion to be implanted may include at least one of H, He, Ar, P, B, BF₂, or As. The dose amount Di of the dopant ion may include a dose amount of at least one of H, He, Ar, P, B, BF₂, or As. The annealing condition Ai of the semiconductor substrate includes at least one of annealing temperature or annealing time. The annealing condition Ai may include the following two parameters: annealing temperature Ali (where i is an integer from 1 to r) and annealing time A2i (where i is an integer from 1 to s).

For a parameter which may take a continuous numerical value, such as a chemical concentration of the impurity, a predetermined range Li is set for each value Ci of the chemical concentration of the impurity. A sample in which the chemical concentration of the impurity is within the range Li is treated as belonging to the corresponding chemical concentration Ci. The same applies to the dose amount Di of the dopant ion, the acceleration energy Ei of the dopant ion, the annealing temperature A1i, and the annealing time A2i.

The correlated information obtainment step S102 in the present example obtains the correlated information in which one defect evaluation value and characteristic of a semiconductor element are associated with each combination of values of the plurality of parameters (Xi, Ci, Yi, Di, Ei, A1i, A2i, Mi). The correlated information in the present example is standard information or a standard information group which allows a reference value of the defect evaluation value to be uniquely decided if the initial characteristic of the semiconductor substrate and the process condition are determined and to which a characteristic of the semiconductor substrate obtained by the reference value corresponds. As an example, the correlated information may obtain a matrix with j×k×l×n×o×q×r×s cells indicating all combinations of the values of the plurality of parameters (Xi, Ci, Yi, Di, Ei, A1i, A2i, Mi). One defect evaluation value and one characteristic of the semiconductor element are associated with each of the cells of the matrix. The actual measurement values of the defect evaluation value may be associated with some cells of the matrix, and the actual measurement values of the defect evaluation value may not be associated with some cells. An estimate value of the defect evaluation value calculated from the actual measurement value of the defect evaluation value for another cell may be associated with a cell with which the actual measurement value of the defect evaluation value is not associated. For example, estimate values of the defect evaluation value for some cells may be generated by interpolating or extrapolating the actual measurement value of the defect evaluation value for another cell, and the estimate values of the defect evaluation value for some cells may be generated by approximating a set of measurement values of the defect evaluation value with a predetermined formula as shown in FIG. 2.

The parameter included in the matrix of the correlated information may be any one or more of the parameters (Xi, Ci, Yi, Di, Ei, A1i, A2i, Mi) described above. The initial characteristic of the semiconductor substrate may include a type of an element which is a main component of the semiconductor substrate. For example, the initial characteristic of the semiconductor substrate may include information indicating whether the semiconductor substrate is a silicon substrate, a silicon carbide substrate, a gallium nitride substrate, or some other substrate. As an example, the semiconductor substrate is the silicon substrate.

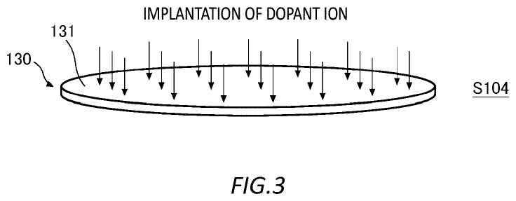

FIG. 3 describes an example of an implantation step S104. The implantation step S104 implants a dopant ion into a principal surface 131 of a substrate for evaluation 130 under a set first process condition. The first process condition may include at least one of the type Yi of the dopant ion, the dose amount Di of the dopant ion, the acceleration energy Ei of the dopant ion, the annealing condition Ai of a semiconductor substrate, and the type Mi of a device for implanting the dopant ion. As an example, the type of the dopant ion is a hydrogen ion (proton). The first process condition may be an initial set value of a process condition to be set in a process of manufacturing a semiconductor device by using a substrate for manufacture, or may be another process condition.

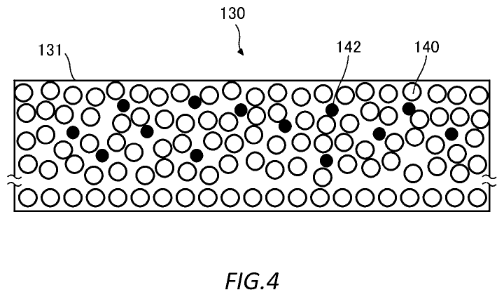

FIG. 4 is a cross-sectional view schematically showing a state in a substrate for evaluation 130 into which a dopant ion has been implanted. FIG. 4 schematically shows silicon atoms 140 and hydrogen atoms 142 in the substrate for evaluation 130. The substrate for evaluation 130 in the present example has not been annealed after being implanted with the dopant ion.

When the dopant ion is implanted from the principal surface 131 of the substrate for evaluation 130, an array of the silicon atoms 140 near the principal surface 131 is disordered, and a lattice defect is formed. In addition, the hydrogen atoms 142 are also present as impurities in a crystal lattice.

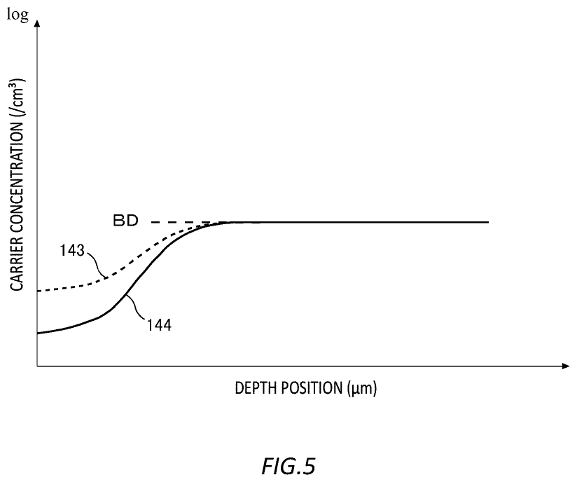

FIG. 5 illustrates an example of distribution of a carrier concentration in a depth direction of the substrate for evaluation 130 shown in FIG. 4. The horizontal axis in FIG. 5 indicates a position in the depth direction with the principal surface 131 as a reference position. The vertical axis in FIG. 5 is a logarithmic axis indicating the carrier concentration. In FIG. 5, the carrier concentration due to a bulk dopant is defined as BD.

As described in FIG. 4, since a lattice defect is formed near the principal surface 131 of the substrate for evaluation 130, the carrier concentration near the principal surface 131 decreases. A region with higher density of the lattice defect has a lower carrier concentration. Note that, even under the same process condition, density of the lattice defect formed in the substrate for evaluation 130 changes depending on an initial characteristic (for example, oxygen concentration, carbon concentration, or the like) of the substrate for evaluation 130. Some lattice defects are attached to, for example, oxygen or carbon in the initial characteristic. Therefore, the density of the lattice defect generated changes depending on the initial characteristic. For example, probability of collision between carbon in the substrate and an implanted ion (helium, hydrogen, or the like) may change, and density of a local lattice defect may change, due to a change of an atom on a lattice site in the semiconductor substrate from silicon to carbon, intrusion of carbon between lattices, or the like. Therefore, as indicated by a characteristic 143 and a characteristic 144 in FIG. 5, even if a dopant ion is implanted under the same process condition, the distribution of the carrier concentration changes depending on the initial characteristic of the substrate for evaluation 130. Therefore, a characteristic of a semiconductor element formed on the substrate for evaluation 130 also varies depending on the initial characteristic of the substrate for evaluation 130.

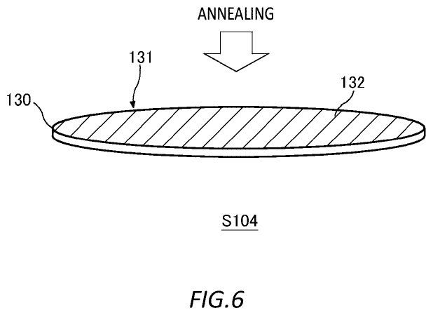

FIG. 6 describes a continuation of the implantation step S104. The implantation step S104 in the present example implants a dopant ion into the substrate for evaluation 130, and then anneals the substrate for evaluation 130 under the annealing condition Ai included in a first process condition. As an example, annealing temperature in the implantation step S104 is 350 degrees Celsius to 420 degrees Celsius, and annealing time is 1 hour to 10 hours, but the annealing condition is not limited thereto. The implantation step S104 may not anneal a semiconductor substrate. In the present specification, a region into which the dopant ion is implanted in the principal surface 131 is referred to as a doping region 132. The doping region 132 may refer to a region before annealing, or may refer to a region after annealing.

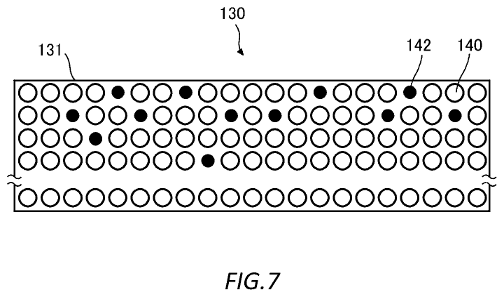

FIG. 7 is a cross-sectional view schematically showing a state in the substrate for evaluation 130 which has been annealed. As a result of a semiconductor substrate being annealed, the silicon atoms 140 and the hydrogen atoms 142 near the principal surface 131 are lattice-matched. The hydrogen atom 142 and a lattice defect become part of the hydrogen donor of a VOH defect, CiOi-H, or interstitial Si—H described above.

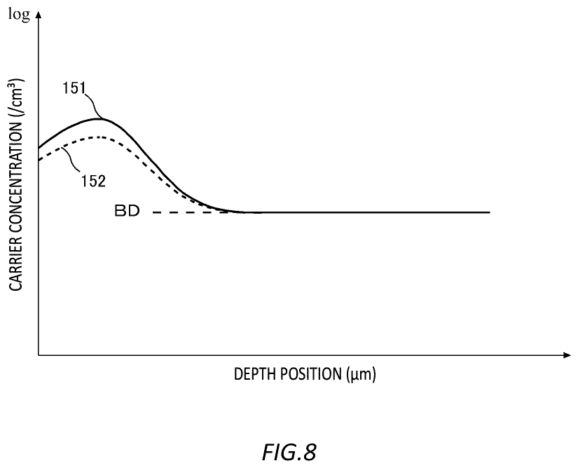

FIG. 8 illustrates an example of distribution of a carrier concentration in a depth direction of the substrate for evaluation 130 shown in FIG. 7. As described in FIG. 7, since a hydrogen donor is formed near the principal surface 131 of the substrate for evaluation 130, the carrier concentration near the principal surface 131 increases. The carrier concentration is a local maximum value at a depth position near an average range of a hydrogen ion. Note that, even under the same process condition, a concentration of the hydrogen donor formed in the substrate for evaluation 130 changes depending on an initial characteristic (for example, oxygen concentration, carbon concentration, or the like) of the substrate for evaluation 130. Therefore, as indicated by a characteristic 151 and a characteristic 152 in FIG. 8, even if a dopant ion is implanted under the same process condition, the distribution of the carrier concentration changes depending on the initial characteristic of the substrate for evaluation 130. Therefore, a characteristic of a semiconductor element formed on the substrate for evaluation 130 also varies depending on the initial characteristic of the substrate for evaluation 130. Note that, since the concentration of the hydrogen donor formed in the substrate for evaluation 130 changes depending on the initial characteristic (for example, oxygen concentration, carbon concentration, or the like) of the substrate for evaluation 130, density of a lattice defect remaining without becoming the hydrogen donor varies.

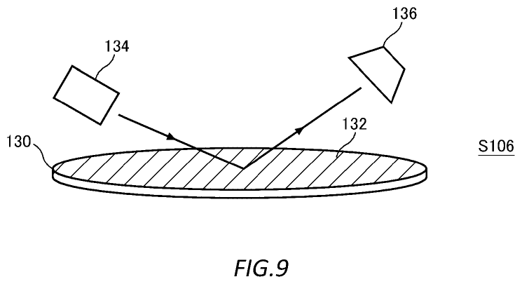

FIG. 9 describes an example of a measurement value obtainment step S106. The measurement value obtainment step S106 obtains a measurement value of a defect evaluation value of the substrate for evaluation 130 in which the doping region 132 has been formed. The measurement value obtainment step S106 may measure the substrate for evaluation 130 which has not been annealed, or may measure the substrate for evaluation 130 which has been annealed.

The measurement value obtainment step S106 obtains the measurement value of the defect evaluation value in the doping region 132 through non-contact measurement. That is, the measurement value obtainment step S106 measures the defect evaluation value without any contact of a probe pin or the like with the substrate for evaluation 130. As a result, it is possible to measure the defect evaluation value while eliminating an influence of a lattice defect formed due to the contact of the probe pin or the like. In addition, since the substrate for evaluation 130 may not be provided with an electrode with which the probe pin or the like is brought into contact, it is possible to measure the defect evaluation value while eliminating the influence of the lattice defect generated when the electrode is formed. The measurement value obtainment step S106 may measure the defect evaluation value without applying current to the substrate for evaluation 130 and without applying voltage.

The measurement value obtainment step S106 in the present example measures the defect evaluation value by Therma Wave measurement. In the Therma Wave measurement, a light source 134 irradiates the doping region 132 with measurement laser light, and a measurement unit 136 measures reflected laser light. The Therma Wave measurement may further use an excitation light source which irradiates the doping region 132 with excitation laser light. The same position may be irradiated with the excitation laser light and the measurement laser light. The Therma Wave measurement can measure density of the lattice defect which has not become a hydrogen donor. In addition, the measurement value obtainment step S106 preferably measures the defect evaluation value of the doping region 132 under the same measurement condition as when the measurement value of the defect evaluation value in correlated information is measured. As described above, the defect evaluation value may be an intensity value of light of a predetermined wavelength detected by the measurement unit 136, or may be a value obtained by performing a predetermined arithmetic operation on the intensity value. The arithmetic operation may convert the intensity value to the density of the lattice defect.

While the examples of FIG. 3 to FIG. 9 have described a variation in the density of the lattice defect for the time when the hydrogen ion is implanted into the substrate for evaluation 130, the density of the lattice defect varies similarly depending on a carbon concentration of the substrate for evaluation 130 or the like when another dopant ion is implanted into the substrate for evaluation 130. For example, in a semiconductor device, a helium ion or the like may be implanted to form a local lattice defect, to adjust carrier lifetime. Similarly to the example of FIG. 4, the helium ion is implanted to form the lattice defect near the principal surface 131. In addition, some of lattice defects disappear as a result of the substrate for evaluation 130 being annealed. In the substrate for evaluation 130, how easily the lattice defect is formed and how easily the lattice defect disappears vary depending on an initial characteristic such as the carbon concentration of the substrate for evaluation 130.

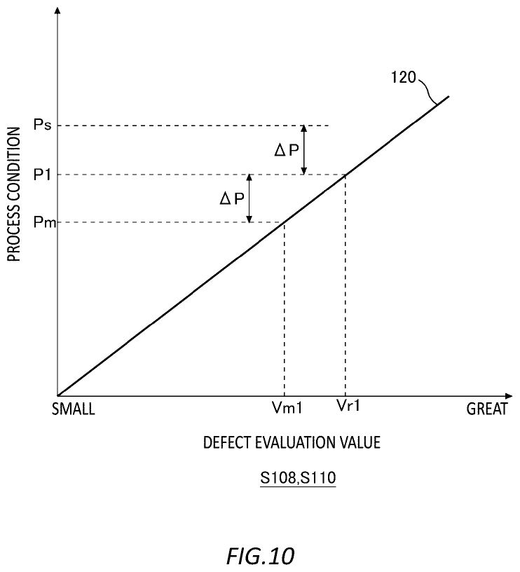

FIG. 10 illustrates an example of a comparison step S108 and an adjustment step S110. The comparison step S108 obtains, in correlated information (approximate line 120 in FIG. 10), a defect evaluation value corresponding to a first process condition P1 as a reference value Vr1. As described above, the first process condition may be an initial set value of a process condition to be set in a process of manufacturing a semiconductor device by using a substrate for manufacture, or may be another process condition.

The comparison step S108 compares a measurement value Vm1 of the defect evaluation value obtained in the measurement value obtainment step S106 with the reference value Vr1. The comparison step S108 may detect a process condition Pm corresponding to the measurement value Vm1 in the correlated information, and calculate a difference ΔP between the process condition Pm and the first process condition P1.

The adjustment step S110 adjusts the process condition in the process of manufacturing the semiconductor device by using the substrate for manufacture, based on a result of comparing the measurement value Vm1 with the reference value Vr1. For example, if a semiconductor device is manufactured under the process condition which has been adjusted, the adjustment step S110 adjusts the process condition such that the defect evaluation value in the semiconductor device is equivalent to the defect evaluation value corresponding to the initial set value of the process condition in the correlated information.

The adjustment step S110 may perform a predetermined arithmetic operation by using the first process condition P1 and the difference ΔP, to calculate a process condition Ps which has been adjusted. The predetermined arithmetic operation may use a formula of the approximate line 120, or may be predetermined based on an empirical rule of a manufacturer of the semiconductor device or the like. For example, it is assumed that the approximate line 120 is a straight line and the initial set value of the process condition is the first process condition P1. If the defect evaluation value Vm1 is lower than the reference value Vr1, when process processing is performed under the process condition P1 corresponding to the reference value Vr1, a characteristic of a semiconductor element will deviate from a characteristic obtained under the process condition P1. Therefore, the process condition is adjusted. In this case, the adjustment step S110 may define a value obtained by adding or subtracting (a value obtained by adding, in the present example) the difference ΔP to or from the first process condition P1, as a value of the process condition Ps which has been adjusted. As a result, the characteristic of the semiconductor element can be the characteristic obtained under the process condition P1. The adjustment step S110 may set the process condition Ps such that an average value of the process condition Ps and Pm matches the first process condition P1. As a result, adjusting the process condition can offset a variation in degree of lattice defect formation depending on an initial characteristic such as an oxygen concentration and a carbon concentration of the semiconductor substrate.

If the process condition includes a plurality of parameters, the adjustment step S110 may select any one or more parameters, to adjust the parameters. The adjustment step S110 may select and adjust any one or more of the dose amount Di of a dopant ion, the annealing temperature A1i, and the annealing time A2i. An adjustable numerical range may be set for each parameter included in the process condition. The adjustable numerical range may be set by the manufacturer of the semiconductor device. The adjustment step S110 may select, as an adjustment target, the parameters in descending order of a range of variation in the defect evaluation value for the time when each parameter is adjusted within each numerical range. If a difference between the measurement value Vm1 of the defect evaluation value and the reference value Vr1 cannot be offset even by adjusting a first parameter having a larger range of variation in the defect evaluation value, the adjustment step S110 may adjust a second parameter having the next largest range of variation in the defect evaluation value.

The manufacture step S112 manufactures the semiconductor device by using the process condition Ps which has been adjusted. The manufacture step S112 manufactures the semiconductor device by using the substrate for manufacture. As an example, although the substrate for manufacture and a substrate for evaluation are different, a partial region of the substrate for manufacture may be used as the substrate for evaluation. For example, a region of the substrate for manufacture where the semiconductor device is not formed may be used as the substrate for evaluation (or doping region 132). Among a plurality of substrate for manufactures used for the semiconductor device, one substrate for manufacture may be provided with a region of the substrate for evaluation, or a plurality of substrate for manufactures may be provided with regions of the substrate for evaluation. This allows initial characteristics of the substrate for manufacture and the substrate for evaluation to be matched.

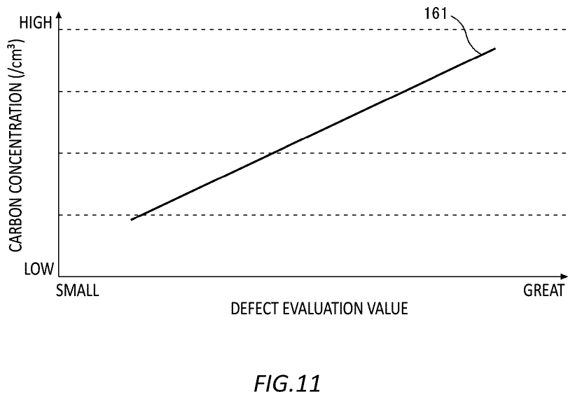

FIG. 11 illustrates an example of first information 161 used to generate correlated information (or approximate line 120). The first information 161 indicates relationship between an initial characteristic (carbon concentration in the example of FIG. 11) of a semiconductor substrate and a defect evaluation value, for a case where the doping region 132 is formed in the semiconductor substrate under a set process condition. The first information 161 in FIG. 11 may be obtained by approximating, with a straight line or the like, measurement results of initial characteristics and defect evaluation values of many samples in which the doping regions 132 are formed under the set process condition. The first information 161 may be a formula of an approximate line as shown in FIG. 11, or may be a table.

The set process condition may be the same as the first process condition P1. In another example, the set process condition may be different from the first process condition P1. The set process condition may be different from the first process condition P1 within a predetermined range.

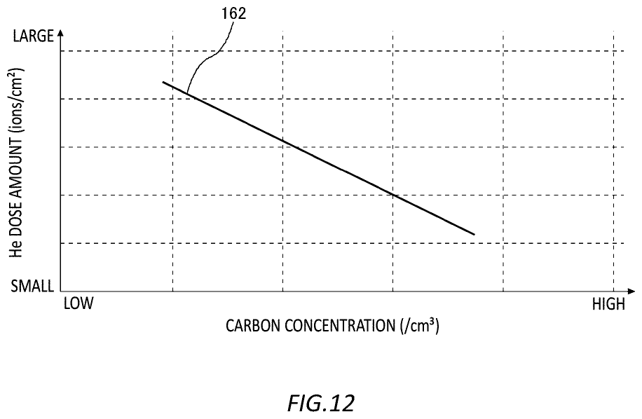

FIG. 12 illustrates an example of second information 162 used to generate correlated information (or approximate line 120). The second information 162 indicates relationship between an initial characteristic (carbon concentration in the example of FIG. 12) of a semiconductor substrate and a process condition (helium dose amount in the example of FIG. 12), for a case where a characteristic of the semiconductor substrate in which the doping region 132 has been formed is a set characteristic value. The characteristic of the semiconductor substrate may be an electrical characteristic. The characteristic of the semiconductor substrate may be the forward voltage Vf under a predetermined condition, may be magnitude of leak current under a predetermined condition, or may be breakdown voltage under a predetermined condition, for a case where a diode including the doping region 132 is formed in the semiconductor substrate. The characteristic of the semiconductor substrate may be collector-emitter voltage Vce under a predetermined condition, may be magnitude of leak current under a predetermined condition, or may be breakdown voltage under a predetermined condition, for a case where a transistor (IGBT, for example) including the doping region 132 is formed in the semiconductor substrate.

The second information 162 may be generated from many samples generated by using diverse process conditions and by using the semiconductor substrate with diverse initial characteristics. A group of samples exhibiting a predetermined electrical characteristic may be extracted from many samples, and the second information 162 may be generated from a combination of an initial characteristic and a process condition of each sample included in the group of samples. The second information 162 may be a formula of an approximate line as shown in FIG. 12, or may be a table. The first information 161 and the second information 162 may be generated from measurement results of the same sample, or may be generated from measurement results of different samples.

The correlated information obtainment step S102 in the present example may obtain the first information 161 and the second information 162, and generate the correlated information (or approximate line 120) from the first information 161 and the second information 162. The first information 161 indicates relationship between the initial characteristic of the semiconductor substrate and a defect evaluation value, and the second information 162 indicates relationship between the initial characteristic of the semiconductor substrate and the process condition. Therefore, relationship between the defect evaluation value and the process condition can be estimated through the initial characteristic of the semiconductor substrate commonly included in the first information 161 and the second information 162. More specifically, the relationship between the defect evaluation value and the process condition can be estimated by extracting the defect evaluation value and the process condition (helium dose amount, for example) having a common value for the initial characteristic (at least one of carbon concentration or oxygen concentration, for example) of the semiconductor substrate in the first information 161 and the second information 162. In the first information 161 and the second information 162, an actual measurement value, or a specification value provided by a manufacturer of the semiconductor substrate or the like may be used as a value of the initial characteristic of the semiconductor substrate. In addition, semiconductor substrates having different initial characteristics such as carbon concentrations may be generated, to measure the first information 161 and the second information 162. Note that the correlated information is not limited to the information generated from the first information 161 and the second information 162.

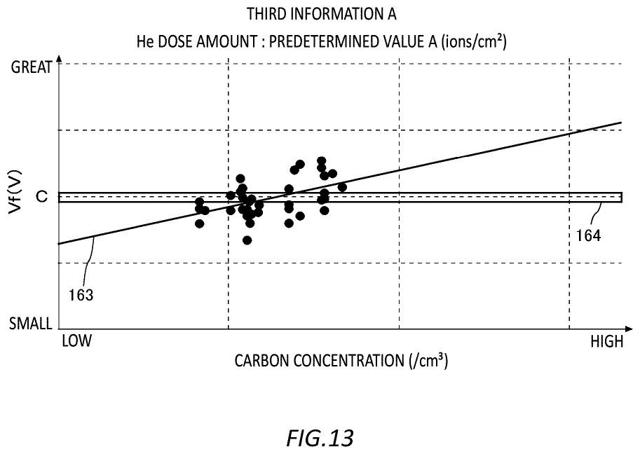

FIG. 13 illustrates an example of third information used to generate the second information 162. The third information indicates relationship between an initial characteristic (carbon concentration in the example of FIG. 13) of a semiconductor substrate and a characteristic value (forward voltage Vf in the example of FIG. 13) of the semiconductor substrate in which the doping region 132 has been formed, for a plurality of samples having different process conditions (helium dose amount in the example of FIG. 13). FIG. 13 shows third information A indicating the relationship between the initial characteristic of the semiconductor substrate and the characteristic value, under one certain process condition (a helium dose amount is a predetermined value A (ions/cm²)). The initial characteristic of the semiconductor substrate may be an actual measurement value, or may be a specification value. The characteristic value of the semiconductor substrate may be the actual measurement value.

There is a correlation between the initial characteristic of the semiconductor substrate and the characteristic value of the semiconductor substrate. In the example of FIG. 13, as indicated by an approximate straight line 163, forward voltage of a diode including the doping region 132 in a current path increases as the carbon concentration of the semiconductor substrate is higher. That is, density of a lattice defect in the doping region 132 is higher and the forward voltage increases as the carbon concentration of the semiconductor substrate is higher.

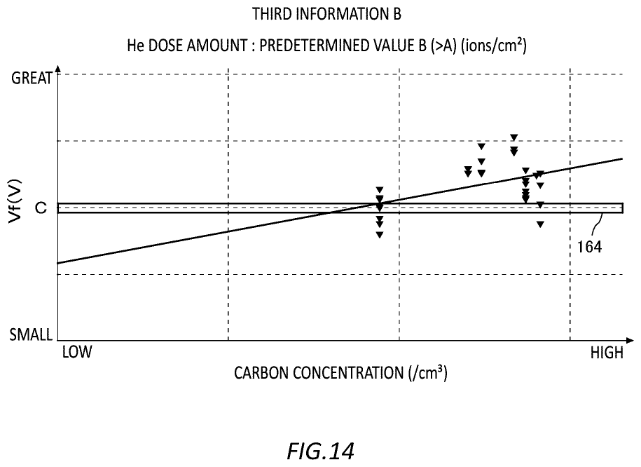

FIG. 14 illustrates an example of third information used to generate the second information 162. FIG. 14 shows third information B indicating relationship between an initial characteristic of a semiconductor substrate and a characteristic value, under one process condition (a helium dose amount is a predetermined value B (ions/cm²) which is a value greater than the predetermined value A) which is different from the example of FIG. 13. The correlated information obtainment step S102 may obtain the third information (the third information A and the third information B, for example), and generate the second information from the third information.

For example, the correlated information obtainment step S102 sets a common characteristic value (Vf=predetermined value C, for example) for the third information A and the third information B. Then, a plurality of samples within a range 164, of which a difference from the common characteristic value C is equal to or smaller than a predetermined value (or the difference is 0), are extracted from the third information A and the third information B. The second information 162 described in FIG. 12 can be obtained, by plotting combinations of initial characteristics (carbon concentrations, for example) of the semiconductor substrate and process conditions (helium dose amounts, for example) in the extracted samples to calculate an approximate line. Note that the second information 162 is not limited to the information generated from the third information. The correlated information (or approximate line 120) described in FIG. 2 can be obtained through the processing described in FIG. 11 to FIG. 14.

In the examples of FIG. 13 and FIG. 14, the third information is generated from samples with two process conditions. In another example, the third information may be generated from samples with three or more process conditions.

In the examples of FIG. 13 and FIG. 14, one characteristic value (value of the forward voltage Vf, for example) of the semiconductor substrate is used. In another example, the correlated information obtainment step S102 may obtain the third information (third information A and third information B, for example) for each of a plurality of types of the characteristic value of the semiconductor substrate. For example, the correlated information obtainment step S102 may obtain the third information for each of at least two of the forward voltage Vf, leak current, breakdown voltage, the collector-emitter voltage Vce of the semiconductor substrate. The correlated information obtainment step S102 may select the third information corresponding to any characteristic value, to generate the second information 162. For example, the correlated information obtainment step S102 may select the third information corresponding to the most important characteristic value among a plurality of characteristic values of the semiconductor substrate. The most important characteristic value may be designated by a user of the semiconductor device, or may be selected by a manufacturer of the semiconductor device.

In the examples of FIG. 1 to FIG. 14, an example has been described in which a value of a concentration of a single impurity is used as the initial characteristic of the semiconductor substrate. For example, the initial characteristic of the semiconductor substrate is a concentration of at least one of carbon or oxygen contained in the semiconductor substrate. In another example, the initial characteristic of the semiconductor substrate may be a sum of concentrations of a plurality of impurities. The initial characteristic of the semiconductor substrate may be a sum of an oxygen concentration and a carbon concentration of the semiconductor substrate. Density of a lattice defect formed in the doping region 132 may be affected by the concentrations of the plurality of impurities such as the oxygen concentration and the carbon concentration. Therefore, the process condition can be precisely adjusted with simple processing by using the sum of the concentrations of the plurality of impurities as the initial characteristic.

The measurement value obtainment step S106 may obtain measurement values of defect evaluation values of the substrate for evaluation 130 in which the doping region 132 has been formed, at a plurality of different timings. For example, the measurement value obtainment step S106 may measure the defect evaluation values at both timings before annealing treatment in the implantation step S104 is started and after the annealing treatment is ended. Alternatively, a defect evaluation value may be measured during the annealing treatment.

The adjustment step S110 may adjust the process condition in a process of manufacturing the semiconductor device by using a substrate for manufacture, based on the measurement values obtained at the plurality of timings. The adjustment step S110 may adjust different process conditions based on the measurement values obtained at respective timings. For example, the adjustment step S110 may adjust a dose amount of an impurity based on the defect evaluation value measured before the annealing treatment is started. In addition, an annealing condition may be adjusted based on the defect evaluation value measured after the annealing treatment is started.

The adjustment step S110 may adjust the process condition in the process of manufacturing the semiconductor device by using the substrate for manufacture, based on an amount of change between the measurement values obtained at the plurality of timings. For example, the adjustment step S110 may obtain the amount of change between the measurement values obtained at the plurality of timings during the annealing treatment. Relationship between a length of annealing time and a measurement value of the defect evaluation value can be obtained from the amount of change. The adjustment step S110 may adjust the length of the annealing time by using the amount of change.

The first process condition described in FIG. 1 to FIG. 14 may be an initial set value of the process condition in the process of manufacturing the semiconductor device by using the substrate for manufacture. If a difference between the measurement value of the defect evaluation value and a reference value is within a set allowable range in the comparison step S108, the adjustment step S110 may not change, from the initial set value, the process condition in the process of manufacturing the semiconductor device by using the substrate for manufacture.

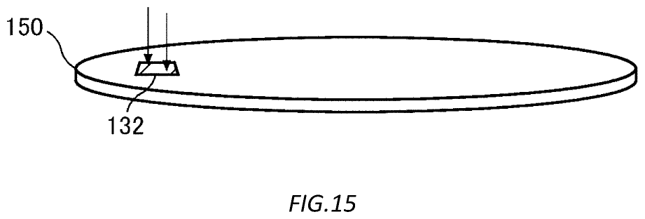

FIG. 15 illustrates another example of a doping region 132. In the examples of FIG. 1 to FIG. 14, the doping region 132 is formed in the substrate for evaluation 130. The doping region 132 in the present example is formed in a partial region of the substrate for manufacture 150. That is, the partial region of the substrate for manufacture 150 in the present example functions as the substrate for evaluation 130. The doping region 132 may be arranged outside a region in which a semiconductor chip is formed.

In the present example, the doping region 132 formed in the substrate for manufacture 150 is measured, to adjust a process condition in a manufacture process for forming a semiconductor element in the substrate for manufacture 150. Specifically, processes of S102 to S110 described in FIG. 1 or the like are performed using the partial region of the substrate for manufacture 150. Subsequently, the manufacture step S112 is performed using the substrate for manufacture 150.

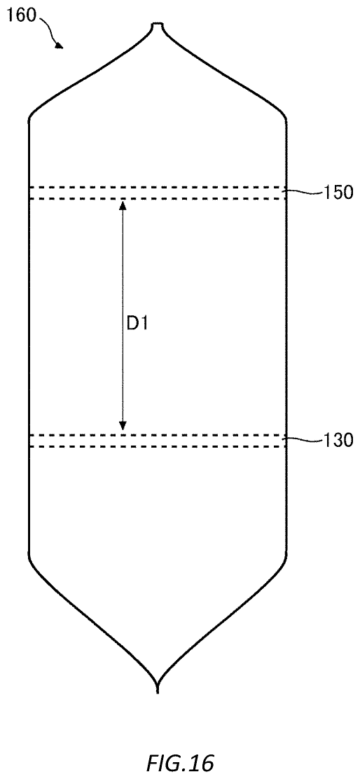

FIG. 16 illustrates an example of a semiconductor ingot 160. A plurality of semiconductor substrates are cut out from the semiconductor ingot 160. Any semiconductor substrate of the plurality of semiconductor substrates may be used as the substrate for evaluation 130. Another semiconductor substrate may be used as the substrate for manufacture 150. As an example, the substrate for evaluation 130 may be used to adjust a process condition of the substrate for manufacture 150 having distance D1 from the substrate for evaluation 130 which is equal to or smaller than a predetermined value. The distance D1 is a distance in a direction perpendicular to a principal surface of each substrate. The distance D1 may be equal to or smaller than half a length of the ingot, may be 70% or less thereof, may be 80% or less thereof, may be 90% or less thereof.

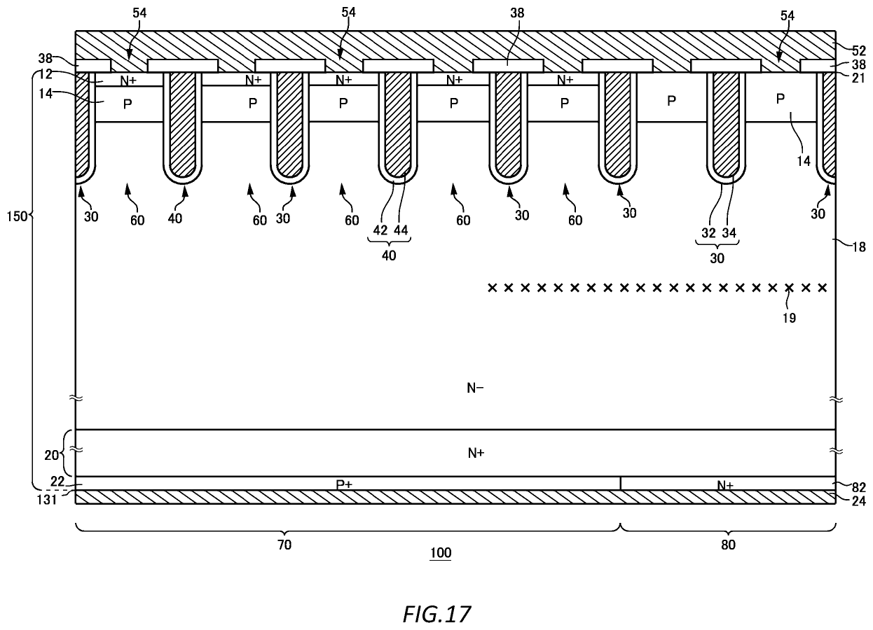

FIG. 17 is a cross-sectional view showing an example of a semiconductor device 100 manufactured in a manufacture step S112. The semiconductor device 100 in the present example is a reverse-conducting IGBT (RC-IGBT) in which a transistor portion 70 and a diode portion 80 are formed on the common substrate for manufacture 150, but a structure of the semiconductor device 100 is not limited to the example of FIG. 17.

The semiconductor device 100 in the present example has the substrate for manufacture 150, an interlayer dielectric film 38, an emitter electrode 52, and a collector electrode 24 in the cross section. The substrate for manufacture 150 in the present example is a silicon substrate, but it may be a semiconductor substrate other than silicon. An upper surface 21 and a lower surface 23 of the substrate for manufacture 150 are examples of the principal surface 131.

The interlayer dielectric film 38 is provided on the upper surface of the substrate for manufacture 150. The interlayer dielectric film 38 is a film including at least one layer of a dielectric film such as silicate glass to which an impurity such as boron or phosphorous is added, a thermal oxide film, and some other dielectric film. A contact hole 54 is provided in the interlayer dielectric film 38.

The emitter electrode 52 is provided on the upper side of the interlayer dielectric film 38. The emitter electrode 52 is in contact with the upper surface 21 of the substrate for manufacture 150 through the contact hole 54 in the interlayer dielectric film 38. The collector electrode 24 is provided on the lower surface 23 of the substrate for manufacture 150. The emitter electrode 52 and the collector electrode 24 are formed of a metal material such as aluminum. In the present specification, a direction in which the emitter electrode 52 and the collector electrode 24 are connected is referred to as a depth direction.

The substrate for manufacture 150 has a drift region 18 of an N type or an N-type. The drift region 18 is provided in each of the transistor portion 70 and the diode portion 80.

In a mesa portion 60 of the transistor portion 70, an emitter region 12 of an N+ type and a base region 14 of a P type are provided in order from an upper surface 21 side of the substrate for manufacture 150. The drift region 18 is provided below the base region 14.

The emitter region 12 is exposed on the upper surface 21 of the substrate for manufacture 150, and is provided in contact with a gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in the present example is provided in contact with the emitter region 12. The base region 14 may be in contact with the trench portions on both sides of the mesa portion 60.

In a mesa portion 61 of the diode portion 80, the base region 14 of the P type is provided in contact with the upper surface 21 of the substrate for manufacture 150. The drift region 18 is provided below the base region 14.

In each of the transistor portion 70 and the diode portion 80, a buffer region 20 of the N+ type may be provided below the drift region 18. A doping concentration of the buffer region 20 is higher than a doping concentration of the drift region 18. The buffer region 20 may have a concentration peak having a higher doping concentration than the drift region 18.

The buffer region 20 may have two or more concentration peaks in the depth direction of the substrate for manufacture 150. The concentration peak of the buffer region 20 may be provided at the same depth position as, for example, that of a chemical concentration peak of hydrogen (proton) or phosphorous. The buffer region 20 may function as a field stopper layer which prevents a depletion layer expanding from a lower end of the base region 14 from reaching a collector region 22 of a P+ type and a cathode region 82 of the N+ type.

In the transistor portion 70, the collector region 22 of the P+ type is provided below the buffer region 20. An acceptor concentration of the collector region 22 is higher than an acceptor concentration of the base region 14. An acceptor of the collector region 22 is, for example, boron.

In the diode portion 80, the cathode region 82 of the N+ type is provided below the buffer region 20. A donor concentration of the cathode region 82 is higher than a donor concentration of the drift region 18. A donor of the cathode region 82 is, for example, hydrogen or phosphorous. Note that an element serving as a donor and an acceptor in each region is not limited to the examples described above. The collector region 22 and the cathode region 82 are exposed on the lower surface 23 of the substrate for manufacture 150, and are connected to the collector electrode 24. The collector electrode 24 may be in contact with the entire lower surface 23 of the substrate for manufacture 150. The emitter electrode 52 and the collector electrode 24 are formed of a metal material such as aluminum.

One or more gate trench portions 40 and one or more dummy trench portions 30 are provided on the upper surface 21 side of the substrate for manufacture 150. Each trench portion is provided from the upper surface 21 of the substrate for manufacture 150 through the base region 14 to below the base region 14. In a region where at least one of the emitter region 12 or a contact region 15 is provided, each trench portion also penetrates these doping regions.

The transistor portion 70 in the present example is provided with the gate trench portion 40 and a dummy trench portion 30. The diode portion 80 in the present example is provided with the dummy trench portion 30, and is not provided with the gate trench portion 40.

The gate trench portion 40 has a gate trench, a gate dielectric film 42, and a gate conductive portion 44 which are provided in the upper surface 21 of the substrate for manufacture 150. The gate dielectric film 42 is provided to cover an inner wall of the gate trench. The gate dielectric film 42 may be formed by oxidizing or nitriding a semiconductor on the inner wall of the gate trench. The gate conductive portion 44 is provided farther inward in the gate trench than the gate dielectric film 42. That is, the gate dielectric film 42 insulates the gate conductive portion 44 from the substrate for manufacture 150. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the substrate for manufacture 150. The gate conductive portion 44 is electrically connected to a gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench, a dummy dielectric film 32, and a dummy conductive portion 34 which are provided in the upper surface 21 of the substrate for manufacture 150. The dummy conductive portion 34 is electrically connected to the emitter electrode 52. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the substrate for manufacture 150. The dummy conductive portion 34 may be formed of the same material as that of the gate conductive portion 44. For example, the dummy conductive portion 34 is formed of a conductive material such as polysilicon or the like. The dummy conductive portion 34 may have the same length as that of the gate conductive portion 44 in the depth direction. The gate trench portion 40 and the dummy trench portion 30 in the present example are covered by the interlayer dielectric film 38 on the upper surface 21 of the substrate for manufacture 150.

A lattice defect 19 may be formed in the diode portion 80. The lattice defect 19 can be formed by locally implanting, for example, an impurity such as helium into the substrate for manufacture 150. Providing the lattice defect 19 can shorten a carrier lifetime. Therefore, reverse recovery time of the diode portion 80 can be shortened, and reverse recovery loss can be reduced.

The adjustment step S110 described in FIG. 1 to FIG. 16 may adjust a process condition (dose amount of a helium ion, annealing time, or the like, for example) in a process of forming the lattice defect 19. The adjustment step S110 may adjust a process condition (dose amount of a hydrogen ion, annealing time, or the like, for example) in a process of forming the buffer region 20. The adjustment step S110 may adjust a process condition in a process of forming another region.

According to the present example, adjustment of the process condition can offset a variation in a characteristic due to variability in an initial characteristic (concentrations of oxygen and carbon, for example) of the substrate for manufacture 150. For example, since a variation in density of the lattice defect 19 can be suppressed, a variation in the forward voltage Vf, magnitude of leak current, or the collector-emitter voltage Vce can be suppressed. In addition, since variations in a donor concentration of the buffer region 20 and the density of the lattice defect can be suppressed, a variation in the magnitude of the leak current or breakdown voltage can be suppressed.

While the present invention has been described by way of the embodiments, the technical scope of the present invention is not limited to the scope described in the above-described embodiments. It is apparent to persons skilled in the art that various alterations or improvements can be made to the above-described embodiments. It is apparent from the description of the claims that embodiments added with such alterations or improvements can also be included in the technical scope of the present invention.

It should be noted that the operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described using phrases such as “first” or “next” in the claims, embodiments, or diagrams for convenience, it does not necessarily mean that the process must be performed in this order.

What is claimed is:

1. A method for manufacturing a semiconductor device, wherein the method:
obtains correlated information indicating relationship between a process condition under which a dopant is implanted into a semiconductor substrate having an initial characteristic to form a doping region, and a defect evaluation value obtained by evaluating density of a defect formed in the doping region;
forms, under a set first process condition, the doping region in a substrate for evaluation, which is the semiconductor substrate having the initial characteristic equal to that of a substrate for manufacture, which is the semiconductor substrate forming the semiconductor device;
obtains a measurement value of the defect evaluation value of the substrate for evaluation in which the doping region has been formed;
obtains, in the correlated information, the defect evaluation value corresponding to the first process condition as a reference value, and compares the measurement value of the defect evaluation value with the reference value; and
adjusts the process condition in a process of manufacturing the semiconductor device by using the substrate for manufacture, based on a result of comparing the measurement value with the reference value.

2. The method for manufacturing a semiconductor device according to claim 1, wherein the method:
obtains:
first information indicating relationship between the initial characteristic of the semiconductor substrate and the defect evaluation value for a case where the doping region is formed in the semiconductor substrate under the process condition which is set; and
second information indicating relationship between the initial characteristic of the semiconductor substrate and the process condition for a case where a characteristic of the semiconductor substrate in which the doping region has been formed is a set characteristic value; and
generates the correlated information from the first information and the second information.

3. The method for manufacturing a semiconductor device according to claim 2, wherein the method:
obtains third information indicating relationship between the initial characteristic of the semiconductor substrate and the characteristic value of the semiconductor substrate in which the doping region has been formed, for a plurality of samples with the process condition being different; and
extracts, in the third information, multiple samples in each of which the characteristic value is within a set range, among the plurality of samples, and generates the second information from the initial characteristic and the process condition in the multiple samples.

4. The method for manufacturing a semiconductor device according to claim 3, wherein the method:
obtains the third information for each of a plurality of types of the characteristic value of the semiconductor substrate; and
selects the third information obtained for any type of the plurality of types of the characteristic value, to generate the second information.

5. The method for manufacturing a semiconductor device according to claim 2, wherein
the initial characteristic in the first information and the second information is a concentration of an impurity contained in the semiconductor substrate.

6. The method for manufacturing a semiconductor device according to claim 5, wherein
the initial characteristic is a concentration of at least one of carbon or oxygen contained in the semiconductor substrate.

7. The method for manufacturing a semiconductor device according to claim 6, wherein
the initial characteristic is a sum of a carbon concentration and an oxygen concentration in the semiconductor substrate.

8. The method for manufacturing a semiconductor device according to claim 1, wherein
the method obtains, through non-contact measurement, the measurement value of the defect evaluation value of the substrate for evaluation in which the doping region has been formed.

9. The method for manufacturing a semiconductor device according to claim 8, wherein
the non-contact measurement is Therma Wave measurement.

10. The method for manufacturing a semiconductor device according to claim 1, wherein
the method obtains, at a plurality of different timings, the measurement value of the defect evaluation value of the substrate for evaluation in which the doping region has been formed, and adjusts the process condition in the process of manufacturing the semiconductor device by using the substrate for manufacture, based on the measurement value at the plurality of timings.

11. The method for manufacturing a semiconductor device according to claim 1, wherein
the process condition includes at least one of a dose amount or acceleration energy of the dopant.

12. The method for manufacturing a semiconductor device according to claim 11, wherein
the process condition further includes at least one of a device for implanting the dopant or an annealing condition of the semiconductor substrate.

13. The method for manufacturing a semiconductor device according to claim 1, wherein
a type of the dopant includes at least one of H, He, Ar, P, B, BF₂, or As.

14. The method for manufacturing a semiconductor device according to claim 1, wherein
the initial characteristic of the semiconductor substrate includes a concentration of at least one of carbon, oxygen, or a bulk dopant contained in the semiconductor substrate.

15. The method for manufacturing a semiconductor device according to claim 1, wherein
the method obtains the measurement value of the defect evaluation value obtained after the dopant is implanted to anneal the substrate for evaluation.

16. The method for manufacturing a semiconductor device according to claim 1, wherein
the first process condition is an initial set value of the process condition in the process of manufacturing the semiconductor device by using the substrate for manufacture, and
if a difference between the measurement value of the defect evaluation value and the reference value is within a set allowable range, the process condition in the process of manufacturing the semiconductor device by using the substrate for manufacture is not changed from the initial set value.

17. The method for manufacturing a semiconductor device according to claim 2, wherein
the method obtains, through non-contact measurement, the measurement value of the defect evaluation value of the substrate for evaluation in which the doping region has been formed.

18. The method for manufacturing a semiconductor device according to claim 3, wherein
the method obtains, through non-contact measurement, the measurement value of the defect evaluation value of the substrate for evaluation in which the doping region has been formed.

19. The method for manufacturing a semiconductor device according to claim 4, wherein
the method obtains, through non-contact measurement, the measurement value of the defect evaluation value of the substrate for evaluation in which the doping region has been formed.

20. The method for manufacturing a semiconductor device according to claim 5, wherein
the method obtains, through non-contact measurement, the measurement value of the defect evaluation value of the substrate for evaluation in which the doping region has been formed.
